(19) United States
(12) Patent Application Publication
(10) Pub. No.: US 2012/0222739 A1
(43) Pub. Date: Sep. 6, 2012

(54) Photovoltaic Apparatus

(75) Inventors: Yu-Li Tsai, Changhua County (TW); Chih-Hung Wu, Taoyuan County (TW)

(73) Assignee: ATOMIC ENERGY COUNCIL-INSTITUTE OF NUCLEAR ENERGY RESEARCH, Taoyuan County (TW)

(21) Appl. No.: 13/038,493

(22) Filed: Mar. 2, 2011

(51) Int. Cl. H01L 31/024

(52) U.S. Cl. 136/259

(57) ABSTRACT

A photovoltaic apparatus includes a substrate, a light-concentrating heat sink unit and a solar cell. The light-concentrating heat sink unit includes a carrier connected to the substrate, at least two fins extending from the carrier, and at least two reflective layers each extending on a related one of the fins. The solar cell includes a lower electrode and a solder layer of low thermal resistance provided between the lower electrode and the carrier.

### BACKGROUND OF INVENTION

1. Field of Invention

The present invention relates to a photovoltaic apparatus and, more particularly, to a photovoltaic apparatus including a light-concentrating heat sink unit.

2. Related Prior Art

An optimal energy gap of a single-junction solar cell is about 1.5 eV, and the related efficiency of conversion of solar energy to electricity is about 25%. The rest of the solar energy is dissipated as heat or reflected into air. The conversion efficiency with a multiple-junction solar cell is higher than the conversion efficiency with a single-junction solar cell. The world record for the convention efficiency of a multi-junction solar cell is about 42%. However, still more than half of the solar energy is wasted.

Referring to FIG. 7, a conventional photovoltaic apparatus includes a solar cell 4 provided on a circuit board 5. The solar cell includes a chip 40 sandwiched between an upper electrode 44 and a lower electrode 46. The solar cell 4 is connected to the circuit board 5 by providing a solder layer 41 between the lower electrode 46 and the circuit board 5. When sun light is incident on the solar cell 4, a portion of the solar energy thereof is converted to electricity. Accordingly, a current flows to a load or battery through the upper electrode 44 and the lower electrode 46. In the condition of light concentration, the current generated from the solar cell is as large as several amperes. Because of thermal resistance, heat accumulates in any point in the solar cell 4 where the thermal conductivity is poor, resulting in both the high temperature of the solar cell 4 and the deterioration of photovoltaic property. Assume that the circuit board 5 is a heat sink, and then the most possible limiting layer for heat transfer is the solder layer 41 for two reasons. At first, the area of the solder layer 41 is small. Secondly, the thermal conductivity of the solder layer 41 is poor. Hence, the solder layer 41 cannot rapidly dissipate the heat from the solar cell 4 when it is illuminated by the sun light. Accordingly, the temperature of the solar cell 4 increases while the conversion efficiency drops.

To overcome the foregoing problem, a highly thermal conductive layer 6 of copper can be electroplated on the lower electrode 46 of the solar cell 4 referring to FIG. 8. Since copper exhibits excellent thermal conductivity, the layer 6 efficiently dissipates the heat from the solar cell 4. It however takes several hours to form the copper layer 6. In addition, the preparation of electrolyte and related equipment also takes a long period of time. Therefore, mass production of the photovoltaic apparatus including the solar cell 4 and the copper layer 6 is difficult.

The present invention is therefore intended to obviate or at least alleviate the problems encountered in prior art.

### SUMMARY OF INVENTION

It is the primary objective of the present invention to provide a photovoltaic apparatus that exhibits excellent heat dissipation and conversion efficiency.

To achieve the foregoing objective, the photovoltaic apparatus includes a substrate, a light-concentrating heat sink unit and a solar cell. The light-concentrating heat sink unit includes a carrier connected to the substrate, at least two fins extending from the carrier, and at least two reflective layers each extending on a related one of the fins. The solar cell includes a lower electrode and a solder layer of low thermal resistance provided between the lower electrode and the carrier.

The substrate may be a circuit board.

The light-concentrating heat sink unit may include a solder layer provided between the carrier and the substrate.

The solder layer of the light-concentrating heat sink unit may be made of silver paste, silver-tin alloy and/or silver-tin-copper alloy.

The carrier and the fins may be made of metal alloy with excellent thermal conductivity.

The metal alloy may include stainless steel, copper, silver, gold, aluminum, and/or related alloy.

Each of the fins may extend from a related one of two opposite edges of the carrier.

The light-concentrating heat sink unit may include three fins and three reflective layers. Each of the fins extends from a related one of three adjacent edges of the carrier. Each of the reflective layers extends on a related one of the fins.

The light-concentrating heat sink unit may include four fins and four reflective layers. Each of the fins extends from a related one of four adjacent edges of the carrier. Each of the reflective layers extends on a related one of the fins.

The solder layer of the solar cell may be made of at least one material selected from the group consisting of silver paste, silver-tin alloy and silver-tin-copper alloy.

In another aspect, the photovoltaic apparatus includes a substrate, a light-concentrating heat sink unit and a solar cell. The light-concentrating heat sink unit includes a circular carrier connected to the substrate, a conical fin diversely extending from the circular carrier, and a conical reflective layer extending on the conical fin. The solar cell is connected to the circular carrier by a solder layer with low thermal resistance.

Other objectives, advantages and features of the present invention will be apparent from the following description referring to the attached drawings.

### BRIEF DESCRIPTION OF DRAWINGS

The present invention will be described via detailed illustration of four embodiments referring to the drawings versus the prior art wherein:

FIG. 1 is a front view of a photovoltaic apparatus according to the first embodiment of the present invention;

FIG. 2 is a perspective view of a light-concentrating heat sink unit used in the photovoltaic apparatus shown in FIG. 1;

FIG. 3 is another front view of the photovoltaic apparatus shown in FIG. 1 with phantom lines for showing heat transfer in the photovoltaic apparatus;

FIG. 4 is a perspective view of a light-concentrating heat sink unit used in a photovoltaic apparatus according to the second embodiment of the present invention;

FIG. 5 is a perspective view of a light-concentrating heat sink unit used in a photovoltaic apparatus according to the third embodiment of the present invention;

FIG. 6 is a perspective view of a light-concentrating heat sink unit used in a photovoltaic apparatus according to the fourth embodiment of the present invention;

FIG. 7 is a front view of a conventional photovoltaic apparatus; and

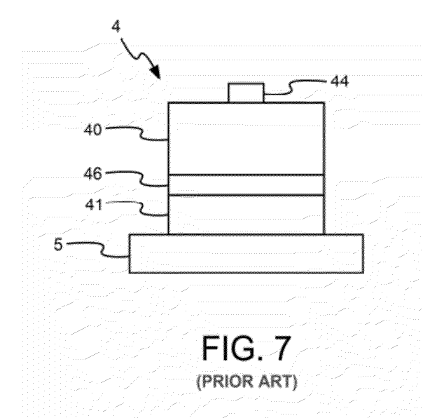

FIG. 8 is a front view of another conventional photovoltaic apparatus.

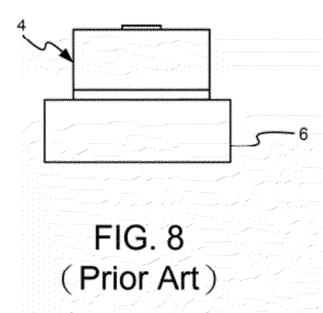

### DETAILED DESCRIPTION OF EMBODIMENTS

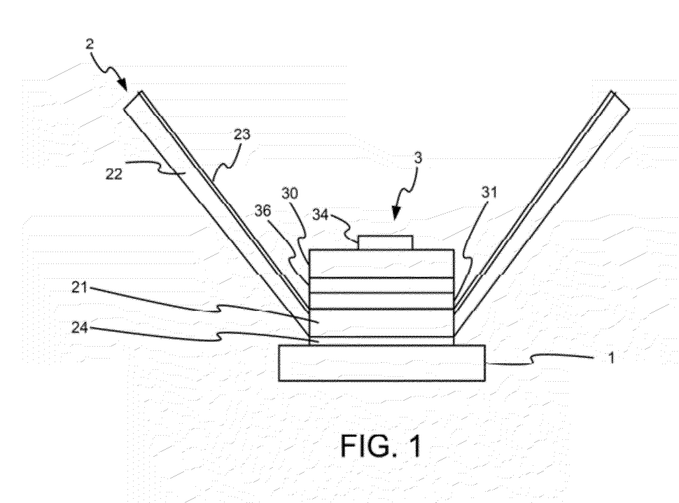

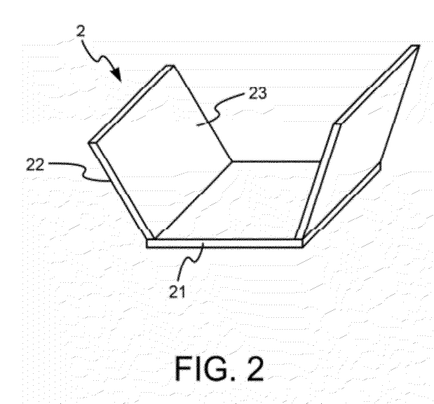

Referring to FIGS. 1 through 3, there is shown a photovoltaic apparatus according to a first embodiment of the present invention. The photovoltaic apparatus includes a substrate 1, a light-concentrating heat sink unit 2 provided on the substrate 1, and a solar cell 3 provided on the light-concentrating heat sink unit 2. The substrate 1 is preferably a circuit board formed with a layout.

The light-concentrating heat sink unit 2 includes a carrier 21, two fins 22, two reflective layers 23 and a solder layer 24. The carrier 21 and the fins 22 are made of a metal alloy with excellent thermal conductivity. The metal alloy includes stainless steel, copper, silver, gold, aluminum, and/or related alloy. The solder layer 24 is made of silver paste, silver-tin alloy and/or silver-tin-copper alloy. The carrier 21 is a flat element. Each of the fins 22 extends upwardly from a related one of two opposite sides of the carrier 21 in an inclined manner. Each of the reflective layers 23 extends on and over an upper side of a related one of the fins 22. The light-concentrating heat sink unit 2 is connected to the substrate 1 by providing the solder layer 24 between the carrier 21 and the substrate 1.

The solar cell 3 includes a chip 30 sandwiched between an upper electrode 34 and a lower electrode 36. The solar cell 3 is connected to the light-concentrating heat sink unit 2 by providing a solder layer 31 between the lower electrode 36 and the carrier 21. The solder layer 31 is made of silver paste, silver-tin alloy and/or silver-tin-copper alloy. The solar cell 3 can be a single-junction, double-junction, triple-junction, quadruple-junction or any other proper multiple-junction solar cell. The present invention can be applied in a III-V solar cell or a non-III-V solar cell such as a silicon-based solar cell.

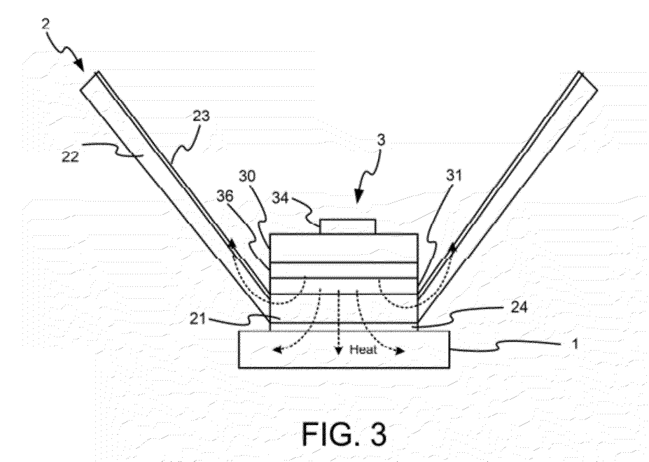

In operation, the reflective layers 23 reflect sun light, thus concentrating the sun light. Hence, a large portion of the sun light is cast on the solar cell 3, and the conversion efficiency is increased. The solar cell 3 converts a portion of the solar energy of the sun light cast thereon to electricity. The other portion of the solar energy is however converted to heat. The heat transfers from the solar cell 3 to the light-concentrating heat sink unit 2 through various paths indicated by the phantom lines in FIG. 3. The total area of the light-concentrating heat sink unit 2 is large to dissipate the heat efficiently.

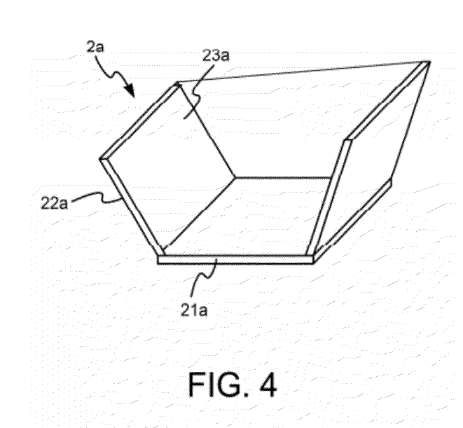

Referring to FIG. 4, there is shown a photovoltaic apparatus according to a second embodiment of the present invention. The second embodiment is identical to the first embodiment except including a light-concentrating heat sink unit 2a instead of the light-concentrating heat sink unit 2. The light-concentrating heat sink unit 2a includes three fins 22a and three reflective layers 23a. Each of the fins 22a extends from a related one of three adjacent sides of the carrier 21. The fins 22a are connected to one another. Each of the reflective layers 23a extends on and over a related one of the fins 22a.

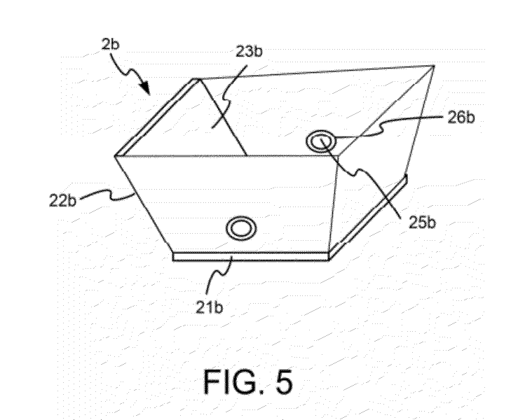

Referring to FIG. 5, there is shown a photovoltaic apparatus according to a third embodiment of the present invention. The third embodiment is identical to the first embodiment except including a light-concentrating heat sink unit 2b instead of the light-concentrating heat sink unit 2. The light-concentrating heat sink unit 2b includes four fins 22b and four reflective layers 23b. Each of the fins 22b extends from a related one of four adjacent sides of the carrier 21. The fins 22b are connected to one another. Each of the reflective layers 23b extends on and over a related one of the fins 22b. An aperture 25 is defined in at least one of the fins 22b and the related reflective layer 23b. An isolative ring 26b is provided along the edge of the aperture 25b. Wiring is executed via the aperture 25b, with the isolative ring 26b used to prevent short-circuit.

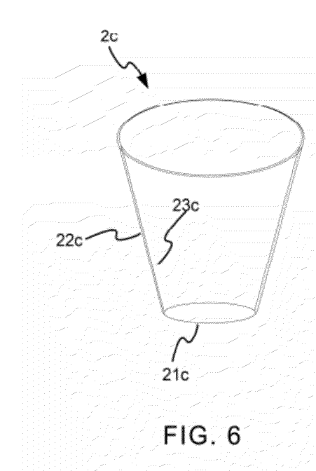

Referring to FIG. 6, there is shown a photovoltaic apparatus according to a fourth embodiment of the present invention. The fourth embodiment is identical to the first embodiment except including a light-concentrating heat sink unit 2c instead of the light-concentrating heat sink unit 2. The light-concentrating heat sink unit 2c includes a circular carrier 21c, a conical fin 22c diversely extending from the circular edge of the circular carrier 21c, and a conical reflective layer 23c extending on and over the conical fin 22c.

The photovoltaic apparatus of the present invention exhibits several advantages over the prior art. At first, the heat dissipation is excellent. This is partly because the thermal conductivity of the light-concentrating heat sink unit is excellent. Another reason is that the total area of the light-concentrating heat sink unit is large compared with that of the solar cell.

Secondly, the light-concentration is excellent. The light-concentrating heat sink unit provides secondary concentration without jeopardizing the heat dissipation.

Thirdly, the cost is low. The provision of the light-concentrating heat sink unit for the solar cell is fast and inexpensive compared with the electroplated copper on the solar cell addressed in the Related Prior Art.

The present invention has been described via the detailed illustration of the embodiments. Those skilled in the art can derive variations from the embodiments without departing from the scope of the present invention. Therefore, the embodiments shall not limit the scope of the present invention defined in the claims.

1. A photovoltaic apparatus comprising:
a substrate 1;
a light-concentrating heat sink unit 2 including a carrier 21 connected to the substrate 1, at least two fins 22 extending from the carrier 21, and at least two reflective layers 23 each extending on a related one of the fins 22; and
a solar cell 3 including a lower electrode 36 and a solder layer 31 with low thermal resistance provided between the lower electrode 36 and the carrier 21.

2. The photovoltaic apparatus according to claim 1, wherein the substrate 1 is a circuit board.

3. The photovoltaic apparatus according to claim 1, wherein the light-concentrating heat sink unit 2 includes a solder layer 24 provided between the carrier 21 and the substrate 1.

4. The photovoltaic apparatus according to claim 3, wherein the solder layer 24 of the light-concentrating heat sink unit 2 is made of at least one material selected from the group consisting of silver paste, silver-tin alloy and silver-tin-copper alloy.

5. The photovoltaic apparatus according to claim 1, wherein the carrier 21 and the fins 22 are made of metal alloy with excellent thermal conductivity.

6. The photovoltaic apparatus according to claim 5, wherein the metal alloy includes at least one material selected from the group consisting of stainless steel, copper, silver, gold, aluminum, and related alloy.

7. The photovoltaic apparatus according to claim 1, wherein each of the fins 22 extends from a related one of two opposite edges of the carrier 21.

8. The photovoltaic apparatus according to claim 1, wherein the light-concentrating heat sink unit 2 includes:
three fins 22a each extending from a related one of three adjacent edges of the carrier 21; and
three reflective layers 23a each extending on a related one of the fins 22a.

9. The photovoltaic apparatus according to claim 1, wherein the light-concentrating heat sink unit 2 includes:
four fins 22b each extending from a related one of four adjacent edges of the carrier 21; and
four reflective layers 23b each extending on a related one of the fins 22b.

10. The photovoltaic apparatus according to claim 1, wherein the solder layer 31 of the solar cell 3 is made of at least one material selected from the group consisting of silver paste, silver-tin alloy and silver-tin-copper alloy.

11. A photovoltaic apparatus comprising:
a substrate 1;
a light-concentrating heat sink unit 2 including a circular carrier 21c connected to the substrate 1, a conical fin 22c diversely extending from the circular carrier 21c, and a conical reflective layer 23c extending on the conical fin 22c; and
a solar cell 3 connected to the circular carrier 21c by a solder layer 31 with low thermal resistance.
